(19) United States
(12) Patent Application Publication
(10) Pub. No.: US 2002/0065619 A1
(43) Pub. Date: May 30, 2002

(54) Battery test module

(76) Inventors: Kevin I. Bertness, Batavia, IL (US); Jamey Butteris, Woodridge, IL (US); Stephen J. McShane, Oak Brook, IL (US)

Correspondence Address: Judson K. Champlin, WESTMAN CHAMPLIN & KELLY, International Centre - Suite 1600, 900 South Second Avenue, Minneapolis, MN, 55402-3319, US

(21) Appl. No.: 09/880,473

(22) Filed: Jun. 13, 2001

Related U.S. Application Data
(63) Continuation-in-part of application No. 09/780,146, filed on Feb. 9, 2001.
(63) Continuation-in-part of application No. 09/544,696, filed on Apr. 7, 2000.
(60) Provisional application No. 60/181,854, filed on Feb. 11, 2000.
(60) Provisional application No. 60/204,345, filed on May 15, 2000.
(60) Provisional application No. 60/218,878, filed on Jul. 18, 2000.
(60) Provisional application No. 60/224,092, filed on Aug. 9, 2000.
(60) Provisional application No. 60/128,366, filed on Apr. 8, 1999.

(51) Int. Cl. G06F 19/00; G01R 31/36

(52) U.S. Cl. 702/63

(57) ABSTRACT

A storage battery includes a battery housing and a plurality of electrochemical cells in the battery housing electrically connected in series to a positive terminal of the battery and a negative terminal of the battery. A first connection is coupled to the positive terminal of the battery and a second connection is coupled to the negative terminal of the battery. A battery test module is mounted to the battery housing and electrically coupled to the positive and negative terminals through the respective first and second Kelvin connection. A display or other output is configured to output a battery test result from the battery test module.

The present application is a Continuation-In-Part of patent application Ser. No. 09/780,146, filed Feb. 9, 2001 which is based on and claims the benefit of U.S. provisional patent application Ser. No. 60/181,854, filed Feb. 11, 2000; U.S. Provisional patent application Ser. No. 60/204,345, filed May 15, 2000; U.S. provisional patent application Ser. No. 60/218,878, filed Jul. 18, 2000; and U.S. provisional patent application Ser. No. 60/224,092, filed Aug. 9, 2000, and is a Continuation-In-Part of and claims priority of U.S. patent application Ser. No. 09/544,696, filed Apr. 7, 2000, which claims the benefit of priority of U.S. provisional patent application Ser. No. 60/128,366, filed Apr. 8, 1999, the contents of which are hereby incorporated by reference in their entirety.

### BACKGROUND OF THE INVENTION

The present invention relates to storage batteries. More specifically, the present invention relates to storage batteries with integral battery testers.

Storage batteries, such as lead acid storage batteries, are used in a variety of applications such as automotive vehicles and standby power sources. Typical storage batteries consist of a plurality of individual storage cells which are electrically connected in series. Each cell can have a voltage potential of about 2.1 volts, for example. By connecting the cells in the series, the voltages of the individual cells are added in a cumulative manner. For example, in a typical automotive storage battery, six storage cells are used to provide a total voltage of about 12.6 volts. The individual cells are held in a housing and the entire assembly is commonly referred to as the “battery.”

It is frequently desirable to ascertain the condition of a storage battery. Various testing techniques have been developed over the long history of storage batteries. For example, one technique involves the use of a hygrometer in which the specific gravity of the acid mixture in the battery is measured. Electrical testing has also been used to provide less invasive battery testing techniques. A very simple electrical test is to simply measure the voltage across the battery. If the voltage is below a certain threshold, the battery is determined to be bad. Another technique for testing a battery is referred to as a load test. In a load test, the battery is discharged using a known load. As the battery is discharged, the voltage across the battery is monitored and used to determine the condition of the battery. More recently, a technique has been pioneered by Dr. Keith S. Champlin and Midtronics, Inc. of Willowbrook, Ill. for testing storage battery by measuring a dynamic parameter of the battery such as the dynamic conductance of the battery. This technique is described in a number of United States patents, for example, U.S. Pat. No. 3,873,911, issued Mar. 25, 1975, to Champlin, entitled ELECTRONIC BATTERY TESTING DEVICE; U.S. Pat. No. 3,909,708, issued Sep. 30, 1975, to Champlin, entitled ELECTRONIC BATTERY TESTING DEVICE; U.S. Pat. No. 4,816,768, issued Mar. 28, 1989, to Champlin, entitled ELECTRONIC BATTERY TESTING DEVICE; U.S. Pat. No. 4,825,170, issued Apr. 25, 1989, to Champlin, entitled ELECTRONIC BATTERY TESTING DEVICE WITH AUTOMATIC VOLTAGE SCALING; U.S. Pat. No. 4,881,038, issued Nov. 14, 1989, to Champlin, entitled ELECTRONIC BATTERY TESTING DEVICE WITH AUTOMATIC VOLTAGE SCALING TO DETERMINE DYNAMIC CONDUCTANCE; U.S. Pat. No. 4,912,416, issued Mar. 27, 1990, to Champlin, entitled ELECTRONIC BATTERY TESTING DEVICE WITH STATE-OF-CHARGE COMPENSATION; U.S. Pat. No. 5,140,269, issued Aug. 18, 1992, to Champlin, entitled ELECTRONIC TESTER FOR ASSESSING BATTERY/CELL CAPACITY; U.S. Pat. No. 5,343,380, issued Aug. 30, 1994, entitled METHOD AND APPARATUS FOR SUPPRESSING TIME VARYING SIGNALS IN BATTERIES UNDERGOING CHARGING OR DISCHARGING; U.S. Pat. No. 5,572,136, issued Nov. 5, 1996, entitled ELECTRONIC BATTERY TESTER WITH AUTOMATIC COMPENSATION FOR LOW STATE-OF-CHARGE; U.S. Pat. No. 5,574,355, issued Nov. 12, 1996, entitled METHOD AND APPARATUS FOR DETECTION AND CONTROL OF THERMAL RUNAWAY IN A BATTERY UNDER CHARGE; U.S. Pat. No. 5,585,728, issued Dec. 17, 1996, entitled ELECTRONIC BATTERY TESTER WITH AUTOMATIC COMPENSATION FOR LOW STATE-OF-CHARGE; U.S. Pat. No. 5,592,093, issued Jan. 7, 1997, entitled ELECTRONIC BATTERY TESTING DEVICE LOOSE TERMINAL CONNECTION DETECTION VIA A COMPARISON CIRCUIT; U.S. Pat. No. 5,598,098, issued Jan. 28, 1997, entitled ELECTRONIC BATTERY TESTER WITH VERY HIGH NOISE IMMUNITY; U.S. Pat. No. 5,757,192, issued May 26, 1998, entitled METHOD AND APPARATUS FOR DETECTING A BAD CELL IN A STORAGE BATTERY; U.S. Pat. No. 5,821,756, issued Oct. 13, 1998, entitled ELECTRONIC BATTERY TESTER WITH TAILORED COMPENSATION FOR LOW STATE-OF-CHARGE; U.S. Pat. No. 5,831,435, issued Nov. 3, 1998, entitled BATTERY TESTER FOR JIS STANDARD; U.S. Pat. No. 5,914,605, issued Jun. 22, 1999, entitled ELECTRONIC BATTERY TESTER; U.S. Pat. No. 5,945,829, issued Aug. 31, 1999, entitled MIDPOINT BATTERY MONITORING; U.S. Pat. No. 6,002,238, issued Dec. 14, 1999, entitled METHOD AND APPARATUS FOR MEASURING COMPLEX IMPEDANCE OF CELLS AND BATTERIES; U.S. Pat. No. 6,037,777, issued Mar. 14, 2000, entitled METHOD AND APPARATUS FOR DETERMINING BATTERY PROPERTIES FROM COMPLEX IMPEDANCE/ADMITTANCE; U.S. Pat. No. 6,051,976, issued Apr. 18, 2000, entitled METHOD AND APPARATUS FOR AUDITING A BATTERY TEST; U.S. Pat. No. 6,081,098, issued Jun. 27, 2000, entitled METHOD AND APPARATUS FOR CHARGING A BATTERY; U.S. Pat. No. 6,091,245, issued Jul. 18, 2000, entitled METHOD AND APPARATUS FOR AUDITING A BATTERY TEST; U.S. Pat. No. 6,104,167, issued Aug. 15, 2000, entitled METHOD AND APPARATUS FOR CHARGING A BATTERY; U.S. Pat. No. 6,137,269, issued Oct. 24, 2000, entitled METHOD AND APPARATUS FOR ELECTRONICALLY EVALUATING THE INTERNAL TEMPERATURE OF AN ELECTROCHEMICAL CELL OR BATTERY; U.S. Pat. No. 6,163,156, issued Dec. 19, 2000, entitled ELECTRICAL CONNECTION FOR ELECTRONIC BATTERY TESTER; U.S. Pat. No. 6,172,483, issued Jan. 9, 2001, entitled METHOD AND APPARATUS FOR MEASURING COMPLEX IMPEDANCE OF CELL AND BATTERIES; U.S. Pat. No. 6,172,505, issued Jan. 9, 2001, entitled ELECTRONIC BATTERY TESTER; U.S. Pat. No. 6,222,369, issued Apr. 24, 2001, entitled METHOD AND APPARATUS FOR DETERMINING BATTERY PROPERTIES FROM COMPLEX IMPEDANCE/ADMITTANCE; and U.S. Pat. No. 6,225,808, issued May 1, 2001, entitled TEST COUNTER FOR ELECTRONIC BATTERY TESTER.

In general, battery testers have been separate pieces of equipment which can be moved between storage batteries and electrically coupled to a storage battery. The prior art has lacked a simple technique for the testing of a storage battery without relying on separate testing equipment.

### SUMMARY OF THE INVENTION

A storage battery includes a battery housing and a plurality of electrochemical cells in the battery housing electrically connected in series to a positive terminal of the battery and a negative terminal of the battery. A first connection is coupled to the positive terminal of the battery and a second connection is coupled to the negative terminal of the battery. A battery test module is mounted to the battery housing and electrically coupled to the positive and negative terminals through the respective first and second Kelvin connection. A display or other output is configured to output a battery test result from the battery test module.

### BRIEF DESCRIPTION OF THE DRAWINGS

FIG. 1 is a side plan view of a storage battery including a battery test module in accordance with the present invention.

FIGS. 2A and 2B are top plan views of the storage battery of FIG. 1.

FIG. 3 is a side cross-sectional view of the storage battery of FIGS. 1 and 2 taken along the line labeled 3-3 in FIG. 2.

FIG. 4 is a block diagram of a storage battery in accordance with the present invention.

FIG. 5 is an electrical diagram of one example embodiment.

FIG. 6 is an electrical diagram of another example embodiment.

### DETAILED DESCRIPTION OF THE ILLUSTRATIVE EMBODIMENTS

In one aspect of the present invention a storage battery is provided having an integrated battery test module for performing a battery test on electrical cells of the storage battery. As used herein “integrated” can include a separate module which is attached to the battery housing. In one embodiment, the battery test module is electrically coupled to the electrical cells of the storage battery through Kelvin connections. In certain aspects, Kelvin connections are not used. As the battery test module is integral with the battery, an operator can test the battery without relying on external battery test equipment. In one embodiment, the battery test is one that can be easily performed by an unskilled operator. Further, the battery test module is preferably manufactured using low cost techniques which may be integrated with a storage battery without an excessive increase in the cost to produce the battery.

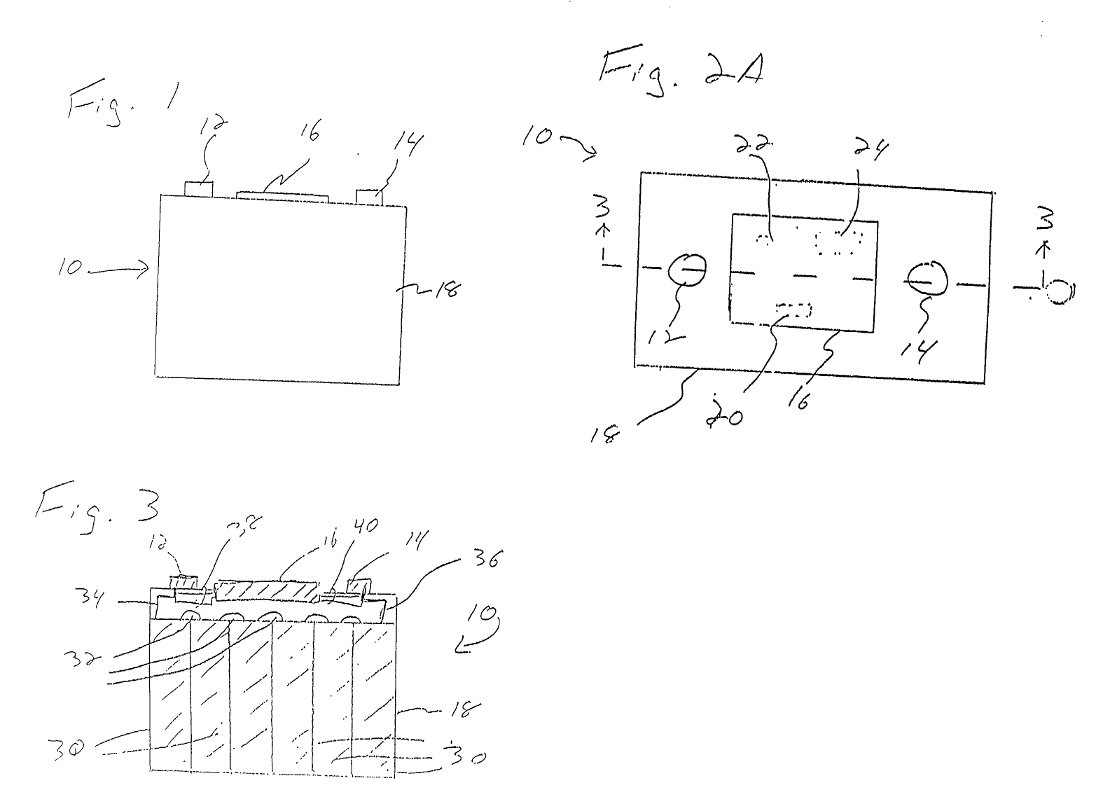

FIG. 1 is a side plan view of a storage battery 10 in accordance with the present invention. Storage battery 10 includes a positive terminal 12 and a negative terminal 14. A battery test module 16 is mounted to a housing 18 of the storage battery.

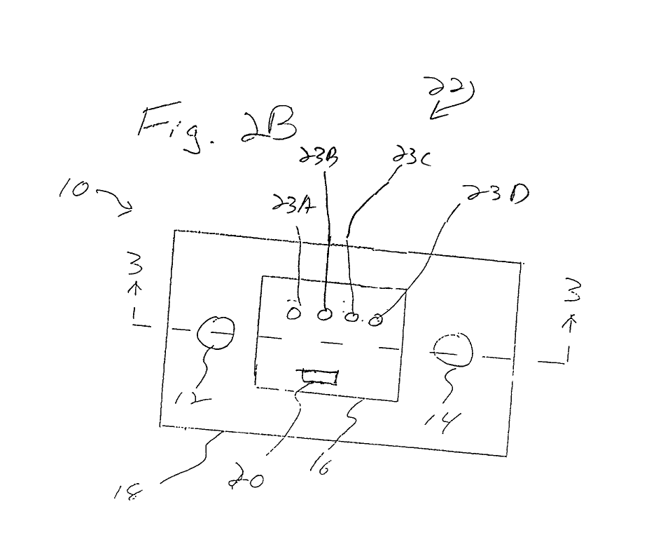

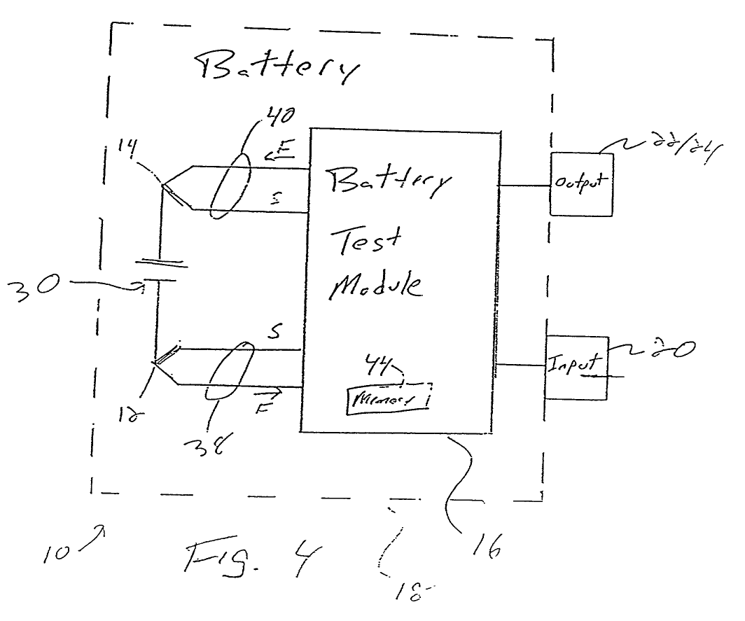

FIGS. 2A and 2B are top plan views of the storage battery 10 of FIG. 1. As illustrated in FIG. 2A, battery test module 16 includes an optional input 20 and optional outputs 22 and 24. Input 20 can be, for example, a push button or other input which can be actuated by an operator. Output 22 can be, for example, an LED or other type of visual indicator which provides a pass/fail indication of a battery test. However, in other aspects, output 24 can be used to send data, using any appropriate technique, to a remote computer or monitoring system. Output 24 can be used to provide a quantitative output of a battery test. In FIG. 2B, the output 22 is in the form of a series of outputs 23A, 23B, 23C and 23D which can comprise LEDs.

FIG. 3 is a side cross-sectional view of battery 10 taken along the line labeled 3-3 in FIG. 2. As illustrated in FIG. 3, battery 10 is a storage battery such as a lead-acid battery and includes a number of electrochemical cells which are electrically connected in series by conductors 32. This forms a string of cells 30 having one end electrically coupled to positive terminal 12 through conductor 34 and having the other end electrically coupled to negative terminal 14 through conductor 36. As illustrated in FIG. 3, battery test module 16 is coupled to terminals 12 and 14 through two pairs of electrical connections which provide Kelvin connections 38 and 40.

In operation, a user can test the condition of battery 10 using battery test module 16. For example, through actuation of button 20 or another input device, a test can be performed on the battery. The results of the battery test are displayed on outputs 22 or 24. In one embodiment, battery test module 16 monitors the battery and waits for a period when the battery is not in use or their is not excessive noise on the electrical system to which the battery is connected and then performs a test on the battery. The results of the battery test can be stored in memory and displayed on output 22 or 24. In such an embodiment, an input such as input 20 is not required to activate the test. However, in such an embodiment, the circuitry within test module 16 could cause the battery to discharge over an extended period.

In the embodiment shown in FIG. 2B, battery test module 16 compares the voltage between terminals 12 and 14 to a number of different threshold voltages. Depending upon the voltage of battery 10, an appropriate number of LEDs 23A-D are illuminated on test module 16. For example, each LED can correspond to a different threshold. These thresholds can be spaced as desired. The LEDs 23A-D can also be of different colors. For example, 23A can be a read LED while 23D can be a green LED. In a slightly more complex embodiment, a load, such as a load resistance, in module 16 can be applied to battery 10 during or prior to a voltage measurement. The output of module 16 can be a function of the applied load.

In one embodiment, test module 16 illuminates outputs 23A-D consecutively until the appropriate threshold is reached. To provide a more desirable user-interface, a small delay can be introduced between the illumination of the each LED. The timing can be as appropriate. The results of the battery test can be maintained on outputs 23A-D for a desired length of time, preferably sufficiently long for a user to observe the test result. In one embodiment, the appropriate number of LEDs remain lit until the test is complete. In another embodiment, only a single LED is lit at a time. Of course, any number of LEDs and thresholds may be used. In other embodiments, additional information can be communicated to an operator by flashing LEDs providing a code or a warning.

The circuitry of the battery tester in the embodiment of FIG. 2B can be implemented using simple comparators and timing circuits as will be apparent to those skilled in the art. A more complex embodiment can include a small microprocessor. Typically, the circuitry of battery test module 16 is powered by storage battery 10.

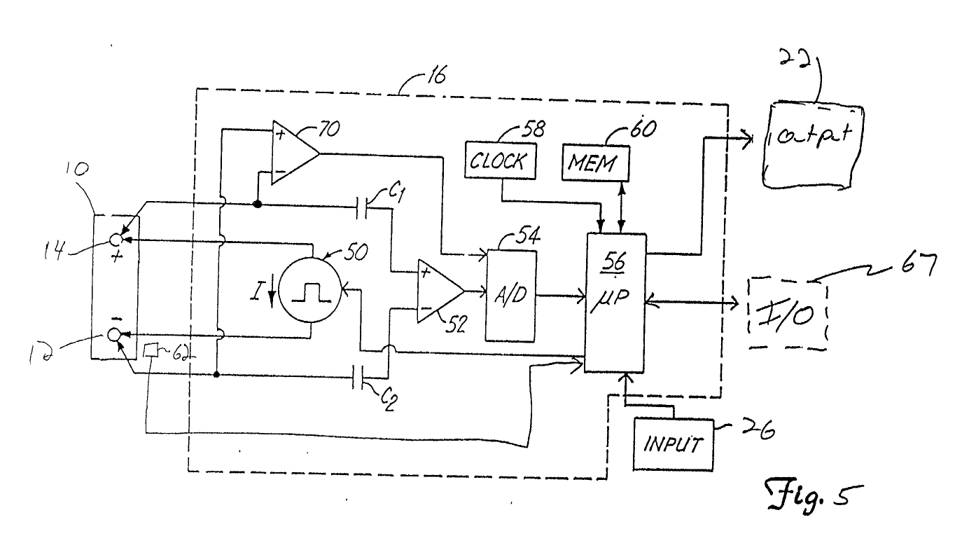

FIG. 4 shows a more detailed view of the electrical connections between battery test module 16 and the cells 30 of the battery 10. Cells 30 are illustrated using the electrical symbol for a battery. Battery test module 16 is coupled to electrochemical cells 30 through Kelvin connections 38 and 40.

A microprocessor in battery test module 16 can store information in memory 44 for later retrieval. For example, information regarding the history of battery usage and battery charging can be maintained in memory for later output. A special access code can be entered through user input 20 to cause the data to be output through output 22 or 24 or other output. In one embodiment, the output can be an audio output such as a series of tones or pre-recorded words. The input can comprise a special series of buttons or timing of pressing of buttons. Alternative inputs can also be provided such as an IR sensor, a vibration sensor, a magnetic switch, a proximity receiver which inductively couples to an external device or others. The output can be provided by energizing an LED in accordance with a digital code which could be read by an external device. Other types of outputs can be provided through an IR link, a proximity communication technique such as inductive coupling, etc. Other techniques include a serial or other hard wired output, RF and optical. Further, a battery test can be initiated based upon an input received through input 20 or 26, using any of the above communication techniques, from a remote computer or other circuitry. This can also be used to initiate a data dump of information stored in memory. Inputs and outputs can also be provided to test module 16 by modulating data onto positive and negative terminals 12 and 14. The data can be received or transmitted using transmit and receive circuitry in battery module 16. Various modulation techniques are known in the art. In one embodiment, the modulation technique is selected such that it does not interfere with external circuitry to which battery 10 may be coupled.

The data recording and reporting technique allows a manufacturer to monitor usage of a battery. For example, the manufacturer could determine that the battery was left in an uncharged condition for an extended period, prior to sale, which caused damage to the battery. The data stored in memory can be keyed to date information if such information is maintained by a microprocessor in battery test module 16 such that various events in the life of the battery 18 can be linked to specific dates. Examples of other information which can be stored in memory 44 include the date of manufacture, battery ratings, battery serial number of other identification, distribution chain, etc.

FIG. 4 also illustrates another aspect of the present invention. In FIG. 4, element 10 can also illustrate a standby jumper or auxiliary system 10 which contains an internal battery 30. Jumper cables or other output such as a cigarette lighter adapter, can couple to battery 30 and can be used to provide auxiliary power to an automotive vehicle. For example, such a system can be used to provide a brief charge to a vehicle or to start a vehicle having a dead battery. This can be used to “jump start” the vehicle. Such devices are known in the art and are typically small, portable devices which contain an internal battery. The internal battery can be, for example, a gel cell, a NICAD battery, a nickel metal hydrate battery or other type of battery. One problem with such auxiliary power systems is that the internal battery can fail without the knowledge of the user. When use of the of auxiliary power system is required, the battery may have failed. Further, the type of a failure may be one which is not easily detected in that the battery may provide a normal voltage output but is not capable of supplying a great deal of current for any period of time. With the present invention, system 10 can also include a test module 16 for testing battery 30. In such an embodiment, a user could periodically test battery 30 to ensure it has not failed. Further, test module 16 can periodically test battery 30 and provide a warning indication such as a flashing light or a warning sound if battery 30 fails. In one aspect of the invention, any type of battery tester can be used to test such an auxiliary battery system.

The present invention can be implemented sing any appropriate technique. One example is set forth in U.S. Pat. No. 6,172,505, issued Jan. 9, 001, and entitled ELECTRONIC BATTERY TESTER which is incorporated herein by reference.

In one aspect, the battery test module determines battery condition based upon a dynamic parameter of the battery, that is a measurement of the battery which is made using a time varying forcing function F as shown in FIG. 4. The resultant signal S in FIG. 4 can be used to determine the dynamic parameter. Example dynamic parameters include dynamic conductance, resistance, impedance and admittance. In another example, single contacts are used to obtain a measurement across the battery.

Memory such as memory 44 within test module 16 can be used to store battery specific information such as the rating of battery 10. The information can be loaded into permanent memory during manufacture. Thus, the user in not required to enter any information regarding the battery. This information can be used in performing the battery test and to provide a qualitative output to a user.

Output 22 can be any type of output including a visual output. Examples include bi or tri-color LEDs. The color along with a flashing condition of an LED can indicate test results such as good, bad, low charge, too low to test, or other conditions and determinations. A flashing LED can be used to indicate system noise, bad cell, or other conditions and determinations. When the user input 20 is used, the circuitry does not provide any drain on the battery except when activated. However, an input such a switch can increase cost and could allow a user to attempt a test at an inopportune time, such as during periods of high system noise.

In embodiments without input 20, test module 16 can wait for a quiet time or other appropriate time to perform a test. The result can be stored in internal memory and periodically displayed on output 22/24 for a brief period. However, extended operation of the test module can drain the battery. In one embodiment, a start-up circuit can be triggered to ‘wake up’ the test module when the battery experiences a voltage increase such as that due to charging of the battery. The circuitry can then enter a ‘sleep’ mode based during period of non-charging in order to save power, for example, shortly after charging stops.

The battery test module of the present invention is preferable integral with the battery For example, the module can be mounted to the housing such as to a top cover of the housing. In various embodiments, the module can be carried within the housing or within an isolated compartment in the housing. The Kelvin connections can couple to the battery terminals either through external or internal conductors.

Of course, the test circuitry and test module can be attached to the battery through any technique including for example, techniques that do not require any modifications to the battery container. For example, it can attach under bolts used on the battery post or can use a press fit or “trap” configuration to fit over the battery posts. This allows the circuitry to be optionally added to existing batteries.

Further, one aspect of the invention includes any tester that is integral with the battery or substantially permanently attached to the battery that provides an output related to a battery condition such as cold cranking amps (CCA) and/or uses Kelvin connections to couple to the battery.

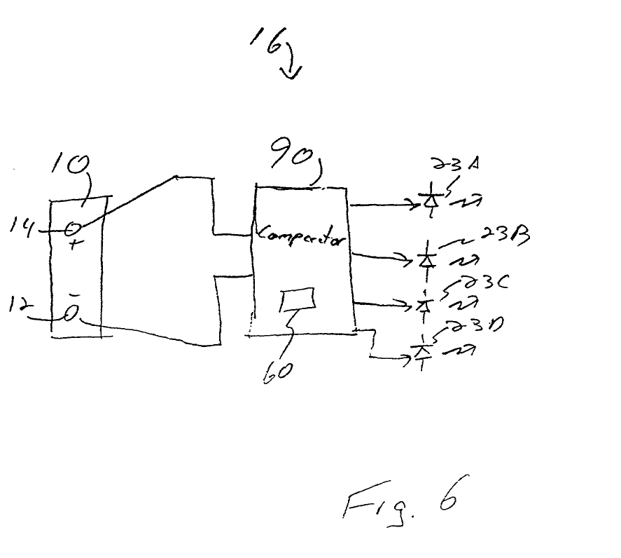

FIG. 5 is a simplified circuit diagram of test module 16. Module 16 is shown coupled to battery 10. Module 16 operates in accordance with one embodiment of the present invention and determines the conductance (G_{BAT}) of battery 10 and the voltage potential (V_{BAT}) between terminals 12 and 14. Module 16 includes current source 50, differential amplifier 52, analog-to-digital converter 54 and microprocessor 56. Amplifier 52 is capacitively coupled to battery 10 through capacitors C₁ and C₂. Amplifier 52 has an output connected to an input of analog-to-digital converter 54. Microprocessor 56 is connected to system clock 58, memory 60, visual output 62 and analog-to-digital converter 54. Microprocessor 56 is also capable of receiving an input from input device 66. Further, an input/output (I/O) port 67 is provided.

In operation, current source 50 is controlled by microprocessor 56 and provides a current in the direction shown by the arrow in FIG. 5. In one embodiment, this is a square wave or a pulse. Differential amplifier 52 is connected to terminals 22 and 24 of battery 10 through capacitors C₁ and C₂, respectively, and provides an output related to the voltage potential difference between terminals 12 and 14. In a preferred embodiment, amplifier 52 has a high input impedance. Circuitry 16 includes differential amplifier 70 having inverting and noninverting inputs connected to terminals 24 and 22, respectively. Amplifier 70 is connected to measure the open circuit potential voltage (V_{BAT}) of battery 10 between terminals 12 and 14. The output of amplifier 70 is provided to analog-to-digital converter 54 such that the voltage across terminals 12 and 14 can be measured by microprocessor 56.

Module 16 is connected to battery 10 through a four-point connection technique known as a Kelvin connection. This Kelvin connection allows current I to be injected into battery 10 through a first pair of terminals while the voltage V across the terminals 12 and 14 is measured by a second pair of connections. Because very little current flows through amplifier 52, the voltage drop across the inputs to amplifier 52 is substantially identical to the voltage drop across terminals 12 and 14 of battery 12. The output of differential amplifier 52 is converted to a digital format and is provided to microprocessor 56. Microprocessor 56 operates at a frequency determined by system clock 58 and in accordance with programming instructions stored in memory 60.

Microprocessor 56 determines the conductance of battery 10 by applying a current pulse I using current source 50. The microprocessor determines the change in battery voltage due to the current pulse I using amplifier 52 and analog-to-digital converter 54. The value of current I generated by current source 50 is known and is stored in memory 60. In one embodiment, current I is obtained by applying a load to battery 10. Microprocessor 56 calculates the conductance of battery 10 using the following equation:

$$Conductance = {G}_{BAT} = \frac{Δ I}{Δ V} 1 \qquad Equation 1$$

where ΔI is the change in current flowing through battery 10 due to current source 50 and ΔV is the change in battery voltage due to applied current ΔI. A temperature sensor 62 can be thermally coupled to battery 10 and used to compensate battery measurements. Temperature readings can be stored in memory 60 for later retrieval.

FIG. 6 is a simple diagram for the embodiment of module 16 shown in FIG. 2B. A comparator 90 can periodically compare a voltage measurement to a plurality of reference levels and responsively energize LEDs 23A-D to provide an indication of the condition of battery 10. This display can be provided or be activated by a switch or other condition. Any of the various features set forth in the Figures and discussion can be used in any appropriate combination and should not be limited to the specific examples shown.

In one aspect of the invention, battery test module 16 is advantageously used while manufacturing and/or during delivery of a vehicle. Module 16 can be installed in battery 10 during the vehicle manufacturing process. As the vehicle moves through the assembly line, various loads are placed on the electrical system. For example, the radio may be run, starter actuated, head lights turned on, etc. Module 16 provides an indication if the battery has been discharged, and should be recharged (or should be replaced due to failure or impending failure) prior to delivery to a dealer or sale to a customer. Module 16 provides an output, such as a visual output to indicate that the battery 10 is discharged and should be recharged.

The module 16 can be configured to store information based on the particular type of rating of battery 10. This can be used in the battery test to determine if the battery should be recharged. Module 16 can be removed from the battery 10 once the vehicle has been assembled or delivered. The module 16 can be reconnected and reused on another vehicle in the assembly line.

With various aspects of the invention, including a module used during manufacture or delivery of a vehicle, module 176 can provide a simple pass/fail visual output, for example through colored LED(s). Additional data can be output to other equipment, for example, by coupling to a data bus of the vehicle, through IR, RF, an external data bus or connection, etc. Additional information can be stored for later retrieval such as information related to battery temperature, usage or cycle history, etc. This data can be time or date stamped and used to diagnose common failures which occur during vehicle manufacturing. Additional information can be stored in the memory such as serial numbers, multiple battery characteristics, self learning, etc.

Although the present invention has been described with reference to preferred embodiments, workers skilled in the art will recognize that changes may be made in form and detail without departing from the spirit and scope of the invention.

What is claimed is:

1. A storage battery, comprising:
a battery housing;
a plurality of electrochemical cells in the battery housing electrically connected in series to a positive terminal of the battery and a negative terminal of the battery;
a first Kelvin connection coupled to the positive terminal of the battery;
a second Kelvin connection coupled to the negative terminal of the battery;
a battery test module mounted to the battery housing and electrically coupled to the positive and negative terminals through respective first and second Kelvin connection; and
an output from the test module configured to output a battery test result from the battery test module.

2. The storage battery of claim 1 wherein the battery test module is configured to output information stored in a memory.

3. The storage battery of claim 1 wherein the test module is attached to the battery after manufacture of the battery.

4. The storage battery of claim 2 wherein the information stored in a memory is output through an electrical connection.

5. The storage battery of claim 1 wherein the Kelvin connections are external to the battery housing.

6. The storage battery of claim 1 wherein the Kelvin connections are internal to the battery housing.

7. The storage battery of claim 3 wherein the test module is attached to posts of the battery.

8. The storage battery of claim 1 wherein the test result is related to battery cold cranking amps (CCA).

9. The storage battery of claim 1 wherein the test result is related to a dynamic parameter of the battery.

10. The storage battery of claim 1 wherein the dynamic parameter is determined as a function of an electrical load to the battery.

11. The storage battery of claim 1 including a temperature sensor thermally coupled to the battery.

12. The storage battery of claim 11 wherein temperature measurements from the temperature sensor are stored in a memory.

13. The storage battery of claim 11 wherein the battery test result is a function of the measured temperature.

14. The storage battery of claim 1 wherein the output comprises at least one LED.

15. The storage battery of claim 1 including a user operable switch configured to initiate output of a battery test result.

16. The storage battery of claim 15 wherein the output battery test result is retrieved from a memory.

17. The storage battery of claim 1 wherein a battery test is performed during periods of non-use of the battery.

18. The storage battery of claim 1 wherein the battery test is performed during periods of reduced noise in the battery.

19. The storage battery of claim 14 wherein the at least one LED is turned on and off in a sequence to convey information.

20. The storage battery of claim 1 wherein the output comprises an audio output.

21. The storage battery of claim 2 including a switch and wherein information is retrieved from the memory only after receipt of a coded input through the switch.

22. The storage battery of claim 1 wherein the output comprises an IR link.

23. The storage battery of claim 1 wherein the output comprises an optical output.

24. The storage battery of claim 1 wherein the output comprises a hard wire output.

25. The storage battery of claim 1 including an input configured to receive a signal to initiate a battery test.

26. The storage battery of claim 1 wherein the output was a proximity communication technique.

27. The storage battery of claim 1 wherein the output is modulated onto a terminal of the battery.

28. The storage battery of claim 2 wherein information stored in the memory includes information related to a date.

29. The storage battery of claim 1 including a memory which stores information related to a rating of the battery and the battery test result is a function of the stored information.

30. A battery test module for testing a storage battery comprising:
a first Kelvin connection configured to couple to a positive terminal of the battery;
a second Kelvin connection configured to couple to a negative terminal of the battery;
a battery test module configured to mount to the storage battery and electrically coupled to the positive and negative terminals through respective first and second Kelvin connections; and
an output from the test module configured to output a battery test result from the battery test module.

31. The battery test module of claim 30 wherein the battery test module is configured to output information stored in a memory.

32. The battery test module of claim 30 wherein the test module is attached to the battery after manufacture of the battery.

33. The battery test module of claim 31 wherein the information stored in a memory is output through an electrical connection.

34. The battery test module of claim 30 wherein the Kelvin connections are external to the battery housing.

35. The battery test module of claim 30 wherein the Kelvin connections are internal to the battery housing.

36. The battery test module of claim 32 wherein the test module is attached to posts of the battery.

37. The battery test module of claim 30 wherein the test result is related to battery cold cranking amps (CCA).

38. The battery test module of claim 30 wherein the test result is related to a dynamic parameter of the battery.

39. The battery test module of claim 30 wherein the dynamic parameter is determined as a function of an electrical load to the battery.

40. The battery test module of claim 30 including a temperature sensor thermally coupled to the battery.

41. The battery test module of claim 40 wherein temperature measurements from the temperature sensor are stored in a memory.

42. The battery test module of claim 40 wherein the battery test result is a function of the measured temperature.

43. The battery test module of claim 30 wherein the output comprises at least one LED.

44. The battery test module of claim 30 including a user operable switch configured to initiate output of a battery test result.

45. The battery test module of claim 44 wherein the output battery test result is retrieved from a memory.

46. The battery test module of claim 30 wherein a battery test is performed during periods of non-use of the battery.

47. The battery test module of claim 30 wherein the battery test is performed during periods of reduced noise in the battery.

48. The battery test module of claim 44 wherein the at least one LED is turned on and off in a sequence to convey information.

49. The battery test module of claim 30 wherein the output comprises an audio output.

50. The battery test module of claim 31 including a switch and wherein information is retrieved from the memory only after receipt of a coded input through the switch.

51. The battery test module of claim 30 wherein the output comprises an IR link.

52. The battery test module of claim 30 wherein the output comprises an optical output.

53. The battery test module of claim 30 wherein the output comprises a hard wire output.

54. The battery test module of claim 30 including an input configured to receive a signal to initiate a battery test.

55. The battery test module of claim 30 wherein the output was a proximity communication technique.

56. The battery test module of claim 30 wherein the output is modulated onto a terminal of the battery.

57. The battery test module of claim 31 wherein information stored in the memory includes information related to a date.

58. The battery test module of claim 30 including a memory which stores information related to a rating of the battery and the battery test result is a function of the stored information.

59. The battery test module of claim 30 wherein the test module is attached to a battery carried in a vehicle during manufacture of the vehicle.

60. The battery test module of claim 59 wherein the battery test module is removed from the vehicle upon completion of the vehicle manufacture.

61. An auxiliary power system, comprising:
an auxiliary battery;
a battery test module electrically coupled to the auxiliary battery and configured to perform a battery test on the auxiliary battery and responsively provide a battery test output; and
an output configured to output results of the battery test output.

62. A method of testing a battery during assembly of an automotive vehicle containing the battery, comprising:
coupling a battery test module to the battery through Kelvin connections to positive and negative terminals of the battery;
performing at least some of the steps required to assemble the automotive vehicle;
performing an electronic test on the battery with the battery test module while performing at least some of the steps required to assemble the automotive vehicle; and
removing the battery test module.

63. The method of claim 62 including outputting a result of the electronic battery test.

64. The method of claim 62 wherein the battery test module is removed subsequent to completion of assembly of the vehicle.
